(19) United States
(12) Patent Application Publication
(10) Pub. No.: US 2022/0240382 A1
(43) Pub. Date: Jul. 28, 2022

(54) FLEXIBLE CIRCUIT BOARD AND METHOD OF MANUFACTURING THE SAME, AND DISPLAY MODULE THEREOF

(71) Applicants: BOE TECHNOLOGY GROUP CO., LTD., Beijing (CN); Beijing BOE Optoelectronics Technology Co., Ltd., Beijing (CN)

(72) Inventors: Dawei ZHANG, Beijing (CN); Zhilong PENG, Beijing (CN); Yingliang ZHANG, Beijing (CN)

(21) Appl. No.: 17/622,146

(22) PCT Filed: Feb. 7, 2021
(86) PCT No.: PCT/CN2021/075800

§ 371 Date: Dec. 22, 2021

(30) Foreign Application Priority Data
Feb. 20, 2020 (CN) 202010103856.7

(51) Int. Cl. H05K 1/11

(52) U.S. Cl. CPC H05K 1/115; H05K 2201/10128; H05K 1/118

(57) ABSTRACT

A flexible circuit board comprises: a flexible substrate, a lead layer, a first insulating layer and a pin layer. The lead layer comprises a plurality of leads provided at one side of the flexible substrate; the first insulating layer is provided at a side of the lead layer facing away from the flexible substrate, the first insulating layer is provided with a plurality of via holes, and the orthographic projection of each via hole on the flexible substrate at least partially overlaps with the orthographic projection of the corresponding lead on the flexible substrate; the pin layer comprises a plurality of pins provided at a side of the first insulating layer facing away from the flexible substrate, the plurality of pins are provided in one-to-one correspondence with the plurality of leads, and the pins are respectively connected to the corresponding leads through the via holes.

### CROSS REFERENCE TO RELATED APPLICATIONS

The present disclosure is based on International Application No. PCT/CN2021/075800, filed on Feb. 7, 2021, which claims the benefit and priority of a Chinese patent application filed on Feb. 20, 2020, with the application number 202010103856.7, titled “FLEXIBLE CIRCUIT BOARD AND MANUFACTURING METHOD THEREFOR, AND DISPLAY MODULE”, and the entire content of the Chinese patent application is incorporated herein by reference.

### TECHNICAL FIELD

The present disclosure relates to the field of display technology, in particular to a flexible circuit board, a method of manufacturing the same, and a display module thereof.

### BACKGROUND

The technology of packaging a driver chip of display panel mainly includes COF packaging and COG packaging technology. COG packaging technology directly binds the driver chip to the display panel through anisotropic conductive adhesive film. COF packaging technology binds the driver chip to the flexible circuit board by utilizing the gold-tin eutectic principle, and the driver chip is connected to the display panel through the flexible circuit board. Compared with the COG packaging technology, the COF packaging technology can avoid setting an area of display panel for binding the driving chip, thereby further reducing the frame width of display panel.

However, due to the bonding characteristics of Au—Sn eutectic, a flip-chip film and the corresponding driver chip cannot be provided with high-density pins (too high pin density will cause short circuits between the pins), and due to the limitation of size of bonding area of driver chip, by using the flip-chip film as the flexible circuit board, fewer output pins can be provided.

The related technology usually solves the technical problem of flexible circuit board with fewer pins through a double-layer flip-chip film. However, the double-layer flip-chip film is expensive and costly.

It should be noted that the information disclosed in the background section above is only used to enhance the understanding of the background of the present disclosure, and therefore may include information that does not constitute prior art known to those of ordinary skill in the art.

### SUMMARY

According to one aspect of the present disclosure, there is provided a flexible circuit board, and flexible circuit board includes: a flexible substrate, a lead layer, a first insulating layer, and a pin layer. The lead layer includes a plurality of leads, and is arranged on a side of the flexible substrate; the first insulating layer is arranged on a side of the lead layer distal to the flexible substrate, a plurality of via holes are provided in the first insulating layer, and orthographic projections of the via holes on the flexible substrate at least partially overlap with orthographic projections of the leads on the flexible substrate; and the pin layer includes a plurality of pins, and is provided on a side of the first insulating layer distal to the flexible substrate, the plurality of pins are arranged in a one-to-one correspondence with the plurality of leads, and the pins are connected to the corresponding leads through the via holes.

In an exemplary embodiment of the present disclosure, the flexible circuit board further includes a second insulating layer disposed between the flexible substrate and the lead layer.

In an exemplary embodiment of the present disclosure, the pin layer includes at least a pin group, each of the pin groups includes a plurality of rows of the pins, each row of the pins are arranged at intervals along a first direction, and two adjacent rows of the pins are staggered in the first direction.

In an exemplary embodiment of the present disclosure, the pin layer includes two rows of the pins.

In an exemplary embodiment of the present disclosure, the pin layer includes a plurality of the pin groups.

In an exemplary embodiment of the present disclosure, the orthographic projections of the plurality of leads on the flexible substrate are arranged at intervals along a first direction, and extend along a second direction, the first direction intersects with the second direction, the lead includes a wiring part and a connecting part, and an orthographic projection of the wiring part on the flexible substrate extends along the second direction; and the connecting part is connected to the wiring part, and a size of the connecting part in the first direction is larger than a size of the wiring part in the first direction; and the orthographic projection of the via hole on the flexible substrate is located on an orthographic projection of the corresponding connecting part on the flexible substrate, and the pin is connected to the corresponding connecting part through the via hole.

In an exemplary embodiment of the present disclosure, a size of the pin in the first direction is larger than a size of the connecting part of the corresponding lead in the first direction, and in the first direction, an orthographic projection of the pin on the flexible substrate cover the orthographic projection of the corresponding connecting part on the flexible substrate.

In an exemplary embodiment of the present disclosure, each of the pins is connected to the corresponding lead through a plurality of the via holes.

In an exemplary embodiment of the present disclosure, the orthographic projections of the plurality of via holes for connecting a same one of the leads, on the flexible substrate are arranged at intervals along the second direction.

In an exemplary embodiment of the present disclosure, the second insulating layer is formed of silicon oxide material.

According to one aspect of the present disclosure, there is provided a method of manufacturing a flexible circuit board, and the method of manufacturing a flexible circuit board includes:

forming a flexible substrate;

forming a lead layer on a side of the flexible substrate, wherein the lead layer includes a plurality of leads;

forming a first insulating layer on a side of the lead layer distal to the flexible substrate, and providing a plurality of via holes on the first insulating layer, wherein orthographic projections of the via holes on the flexible substrate at least partially overlap with orthographic projections of the leads on the flexible substrate; and

forming a pin layer on a side of the first insulating layer distal to the flexible substrate, wherein the pin layer includes a plurality of pins, and is are disposed on the side of the first insulating layer distal to the flexible substrate, the plurality of pins are arranged in a one-to-one correspondence with the plurality of leads, and the pins are connected to the corresponding leads through the via holes.

In an exemplary embodiment of the present disclosure, the method further includes: forming a second insulating layer between the flexible substrate and the lead layer.

In an exemplary embodiment of the present disclosure, the pin layer includes at least a pin group, each of the pin groups includes a plurality of rows of the pins, each row of the pins are arranged at intervals along a first direction, and two adjacent rows of the pins are staggered in the first direction.

In an exemplary embodiment of the present disclosure, the orthographic projections of the plurality of leads on the flexible substrate are arranged at intervals along a first direction, and extend along a second direction, the first direction intersects with the second direction, the lead includes: a wiring part and a connecting part, and an orthographic projection of the wiring part on the flexible substrate extends along the second direction; and the connecting part is connected to the wiring part, and a size of the connecting part in the first direction is larger than a size of the wiring part in the first direction; and the orthographic projection of the via hole on the flexible substrate is located on an orthographic projection of the corresponding connecting part on the flexible substrate, and the pin is connected to the corresponding connecting part through the via hole.

In an exemplary embodiment of the present disclosure, a size of the pin in the first direction is larger than a size of the connecting part of the corresponding lead in the first direction, and in the first direction, an orthographic projection of the pin on the flexible substrate cover the orthographic projection of the corresponding connecting part on the flexible substrate.

In an exemplary embodiment of the present disclosure, each of the pins is connected to the lead through a plurality of the via holes.

In an exemplary embodiment of the present disclosure, the orthographic projections of the plurality of via holes for connecting a same one of the leads, on the flexible substrate are arranged at intervals along the second direction.

In an exemplary embodiment of the present disclosure, the pin layer includes a plurality of pin groups.

According to one aspect of the present disclosure, there is provided a display module, and the display module includes: a display panel; the above flexible circuit board, a driving chip, and a control motherboard, the flexible circuit board is bound to the display panel through an anisotropic conductive adhesive film; the driving chip is bound to the flexible circuit board through an anisotropic conductive adhesive film; and the control motherboard is bound to the flexible circuit board through an anisotropic conductive adhesive film.

It should be understood that the above general description and the following detailed description are only exemplary and explanatory, and cannot limit the present disclosure.

### BRIEF DESCRIPTION OF THE DRAWINGS

The drawings herein are incorporated into the specification and constitute a part of the specification, show embodiments consistent with the disclosure, and are used together with the specification to explain the principle of the disclosure. Apparently, the drawings in the following description are only some embodiments of the present disclosure. For those of ordinary skill in the art, other drawings can be obtained based on these drawings without creative work.

FIG. 1 is a structural layout of an exemplary embodiment of the flexible circuit board of the present disclosure.

FIG. 2 is a cross-sectional view of the dashed line A-A in FIG. 1.

FIG. 3 is a structural layout of the lead layer in FIG. 1.

FIG. 4 is a structural layout of the pin layer in FIG. 1.

FIG. 5 is a cross-sectional view of another exemplary embodiment of the flexible circuit board of the present disclosure.

FIG. 6 is a schematic structural diagram of another exemplary embodiment of the flexible circuit board of the present disclosure.

FIG. 7 is a flowchart of an exemplary embodiment of a method of manufacturing of the flexible circuit board of the present disclosure.

FIG. 8 is a schematic structural diagram of an exemplary embodiment of the display module of the present disclosure.

FIG. 9 is a cross-sectional view of the dashed line B-B in FIG. 8.

### DETAILED DESCRIPTION

Example embodiments will now be described more fully with reference to the accompanying drawings. However, the example embodiments can be implemented in various forms, and should not be construed as being limited to the examples set forth herein; on the contrary, the provision of these embodiments makes the present disclosure more comprehensive and complete, and fully conveys the concept of the example embodiments to those skilled in the art. The same reference numerals in the figures represent the same or similar structures, and thus their detailed descriptions will be omitted.

Although relative terms such as “upper” or “lower” are used in this specification to describe the relative relationship between one component and another component indicated in the drawings, these terms are used in this specification only for convenience, for example, the direction of the example described according to the drawings. It can be understood that, if the device indicated in the drawings is turned over to be upside down, the component described as “upper” will become the “lower” component. Other relative terms, such as “high”, “low”, “top”, “bottom”, “left”, “right”, etc., have similar meanings. When a certain structure is “on” another structure, it may mean that the certain structure is integrally formed on the said another structure, or that the certain structure is “directly” arranged on the said another structure, or that the certain structure is “indirectly” arranged on the said another structure through further another structure.

The terms “a”, “an”, and “the” are used to express the presence of one or more elements/components/etc.; the terms “include” and “have” are used to express the open-ended meaning of inclusion and refer to in addition to the listed elements/compositions/etc., there may be other elements/compositions/etc.

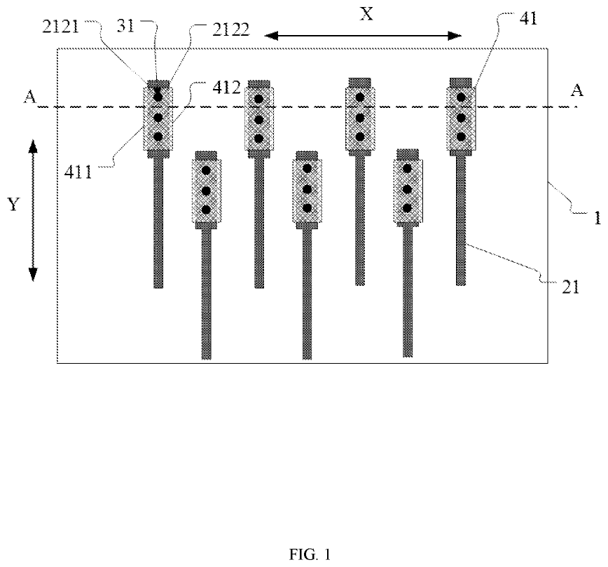

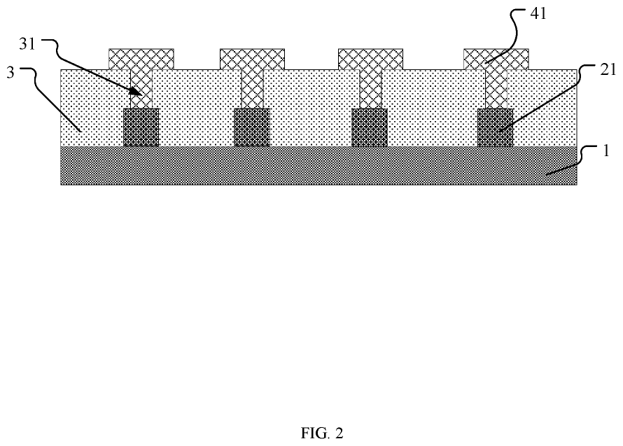

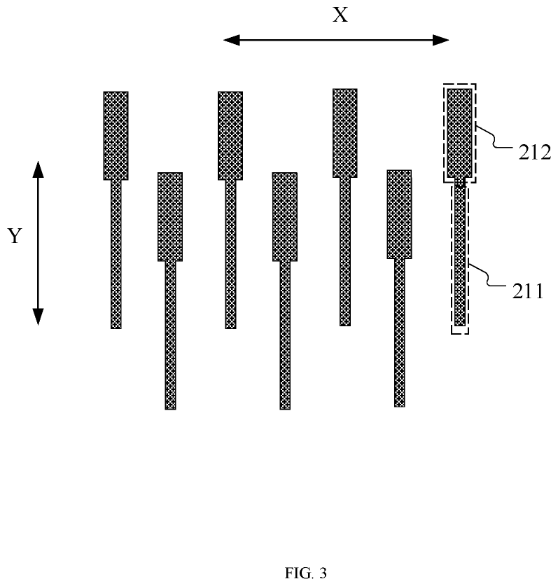

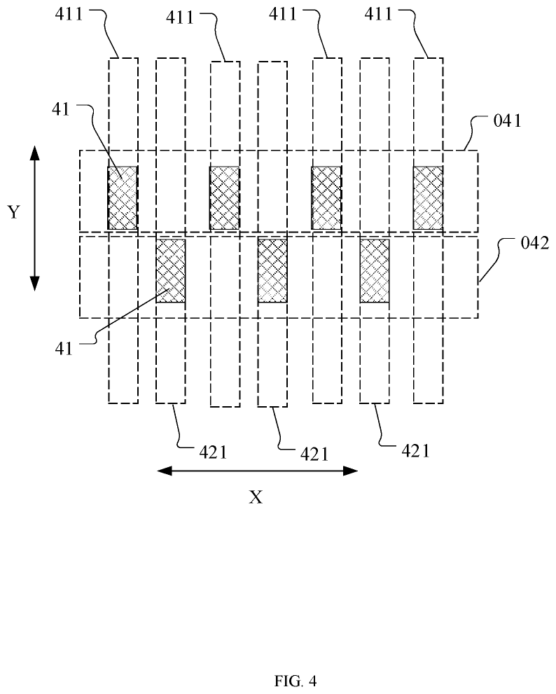

The exemplary embodiment provides a flexible circuit board, as shown in FIGS. 1, 2, 3, and 4, FIG. 1 is a structural layout of an exemplary embodiment of the flexible circuit board of the present disclosure, FIG. 2 is a cross-sectional view of the dashed line A-A in FIG. 1, FIG. 3 is a structural layout of the lead layer in FIG. 1, and FIG. 4 is a structural layout of the pin layer in FIG. 1. In the drawings, a flexible substrate is in a flattened state. The flexible circuit board includes: a flexible substrate 1, a lead layer, a first insulating layer 3, and a pin layer. The lead layer includes a plurality of leads 21, and the lead layer may be arranged on a side of the flexible substrate 1. The first insulating layer 3 may be arranged on a side of the lead layer distal to the flexible substrate 1. A plurality of via holes 31 may be provided in the first insulating layer 3, and orthographic projections of the via holes 31 on the flexible substrate may at least partially overlap with orthographic projections of the leads 21 on the flexible substrate. The pin layer may be provided on a side of the first insulating layer 3 distal to the flexible substrate 1. The pin layer may include a plurality of pins 41, the plurality of pins 41 are arranged in a one-to-one correspondence with the plurality of leads 21, and the pins 41 can be connected to the corresponding leads 21 through the via holes 31.

The pins in the flexible circuit board can be formed by a patterning process. For example, the flexible circuit board can be formed by a patterning device for manufacturing an array substrate in a display panel. Since the patterning process can reach a higher precision, the pins 41 can reach a higher density. In addition, the flexible circuit board can be bound with the driving chip (with a larger number of pins) in the COG packaging technology through an anisotropic conductive adhesive film. On the one hand, the flexible circuit board can output more pins in a limited size, on the other hand, the flexible circuit board has a simple structure and low cost.

As shown in FIGS. 1-4, in the exemplary embodiment, the orthographic projections of a plurality of leads 21 on the flexible substrate may be arranged at intervals along a first direction X, and extend along a second direction Y, and the first direction may intersect with the second direction, for example, the first direction is perpendicular to the second direction. The lead 21 may include a wiring part 211 and a connecting part 212, an orthographic projection of the wiring part 211 on the flexible substrate may extend along the second direction Y, the connecting part 212 may be connected to the wiring part 211, a size of the connecting part 212 in the first direction X may be larger than a size of the wiring part 211 in the first direction X. The orthographic projection of the via hole 31 on the flexible substrate may be located on an orthographic projection of the corresponding connecting part 212 on the flexible substrate, and the pin 41 may be connected to the corresponding connecting part 212 through the via hole 31. Orthographic projections of the plurality of pins 41 on the flexible substrate may be arranged at intervals along the first direction X, and extend along the second direction Y, as well.

As shown in FIGS. 1-4, both the connecting part 212 and the pin 41 may be rectangular, and the via hole 31 may be circular. It should be understood that, in other exemplary embodiments, the connecting part 212, the pin 41, and the via hole 31 may have other shapes as well. For example, the connecting part 212, the pin 41, and the via hole 31 may be circular, trapezoidal, or the like.

As shown in FIGS. 1-4, in the exemplary embodiment, a size of the pin 41 in the first direction X may be larger than the size of the corresponding connecting part 212 (that is, the connecting part of the lead corresponding to the pin) in the first direction X, and in the first direction X, the orthographic projection of the pin 41 on the flexible substrate can cover the orthographic projection of the corresponding connecting part 212 on the flexible substrate. Wherein, as shown in FIG. 1, the pin 41 may include a side 411 and a side 412 that are disposed oppositely in the first direction X, the connecting part 212 may include a side 2121 and a side 2122 that are disposed oppositely in the first direction X. In the first direction X, the orthographic projection of the pin 41 on the flexible substrate can cover the orthographic projection of the corresponding connecting part 212 on the flexible substrate, which can be understood as: orthographic projections of the side 2121 and the side 2122 of the connecting part 212 on the flexible substrate are located between orthographic projections of the side 411 and the side 412 of the pin 41 on the flexible substrate.

As shown in FIGS. 1-4, in the exemplary embodiment, each pin 41 may be connected to the lead through a plurality of via holes 31. The orthographic projections of the plurality of via holes 31 for connecting the same lead 21, on the flexible substrate may be arranged at intervals along the second direction Y. For example, as shown in FIGS. 1-4, each pin 41 may be connected to the lead 21 through three via holes 31. It should be understood that, in other exemplary embodiments, each of the pins 41 may be connected to the leads through other numbers of via holes 31. The number of via holes corresponding to the respective pins 41 can be the same or different.

In the exemplary embodiment, the flexible substrate 1 may be composed of polyimide acid material, and the flexible substrate formed of the polyimide acid material has good bending properties. The lead layer may be made of metal material or alloy material. For example, the lead layer may be metal or alloy material such as Cu, Mo/Cu, NiCr/Cu, Ni/Cu, Cr/Cu, Ti/Al/Ti. The leads of lead layer can be used to form connecting wires. For example, when the flexible circuit board is used for packaging the driver chip of display panel, the leads can be used to connect the display panel and the driver chip, and to connect a control motherboard and the driver chip. The driving chip may include a source driving circuit for generating data signals, a touch signal driving circuit for generating touch signals, and the like. The control motherboard may include a clock control circuit for generating a clock signal and a control signal, and the clock signal and the control signal may be used to control driving circuits such as the source driving circuit, the touch signal driving circuit, etc., to generate corresponding driving signals. The pin layer may be composed of indium tin oxide material. The first insulating layer 3 may be composed of silicon oxide material, and the pins of pin layer are used to bind external components such as the driving chip, the display panel, and the control motherboard. One pin can be connected to the corresponding lead through a plurality of via holes to reduce resistance between the pin and the lead, and at the same time, the plurality of via holes are redundantly arranged to improve stability of the flexible circuit board.

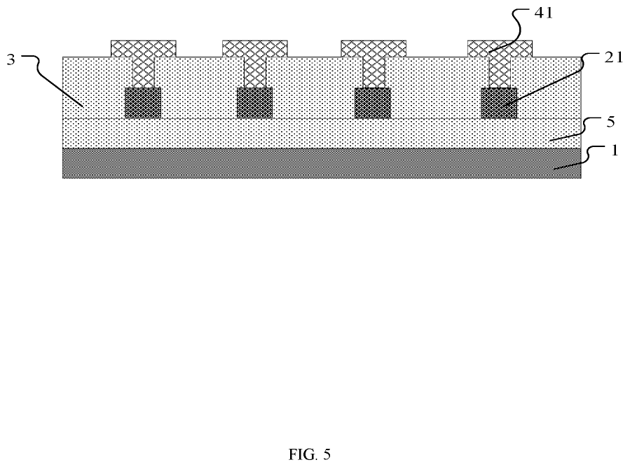

In the exemplary embodiment, as shown in FIG. 5, it is a cross-sectional view of another exemplary embodiment of the flexible circuit board of the present disclosure. The flexible circuit board may further include a second insulating layer 5, and the second insulating layer 5 may be disposed between the flexible substrate and the lead layer. In the exemplary embodiment, the second insulating layer 5 may be formed of silicon oxide (SiOx) material. The second insulating layer formed of the SiOx material has the effect of isolating water and oxygen, and can prevent organic matter and moisture in the flexible substrate from affecting the subsequent processes. It should be understood that the second insulating layer can be composed of other inorganic material as well. Inorganic material has better water and oxygen barrier properties. Any side of the inorganic layer can be further provided with an organic layer. The organic layer can perform a planarization process to the surface of the inorganic layer, so that the inorganic layer has a better effect of isolating water and oxygen.

In the exemplary embodiment, the pin layer may include a pin group, as shown in FIG. 1, FIG. 1 exemplarily shows a distribution diagram of a pin group, and the pin group includes two rows of pins 41. Each row of pins 41 may be arranged at intervals along the first direction X, and two adjacent rows of pins 41 may be staggered in the first direction X. As shown in FIG. 4, two adjacent rows of pins 41 may include a first pin row 041 and a second pin row 042. The first pin row 041 and the second pin row 042 respectively include a plurality of pins 41. Areas covered by the plurality of pins 41 in the first pin row 041 moving in the second direction Y is a plurality of first strip-shaped areas 411 arranged at intervals along the first direction X and extending along the second direction Y. Areas covered by the plurality of pins 41 in the second pin row 042 moving in the second direction Y is a plurality of second strip-shaped areas 421 arranged at intervals along the first direction X and extending along the second direction Y. The two adjacent rows of pins 41 may be staggered in the first direction X, which can be understood as that the first strip-shaped areas 411 formed by the plurality of pins in the first pin row 041 and the second strip-shaped areas 421 formed by the plurality of pins in the second pin row 042 are alternately arranged in the first direction X and do not intersect each other. This arrangement can realize that a larger number of pins are formed on the flexible circuit board within in the limited size in the first direction X. It should be understood that the pin group may include other numbers of rows of pins as well, each row of pins are arranged at intervals along the first direction X, and two adjacent rows of pins 41 may be staggered in the first direction X.

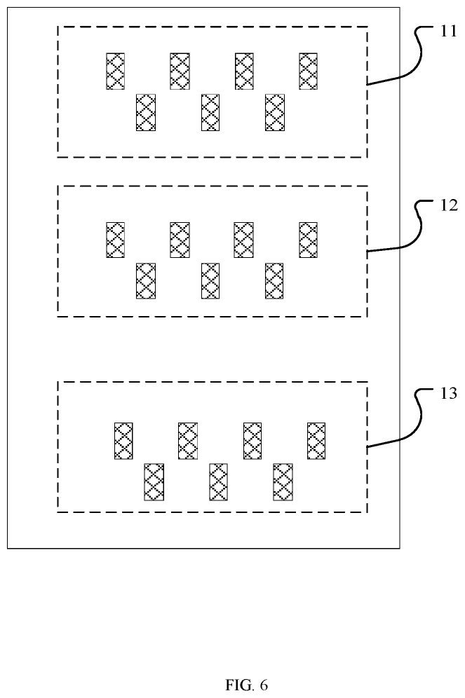

In the exemplary embodiment, the pin layer may include a plurality of pin groups. For example, as shown in FIG. 6, which is a schematic structural diagram of another exemplary embodiment of the flexible circuit board of the present disclosure, the pin layer may include three pin groups 11, 12, and 13, each of which includes a plurality of pins. Each pin group is used to connect different external components. For example, the pin group 11 can be used to connect to the display panel, the pin group 12 can be used to connect to the driver chip, and the pin group 13 can be used to connect to the control motherboard.

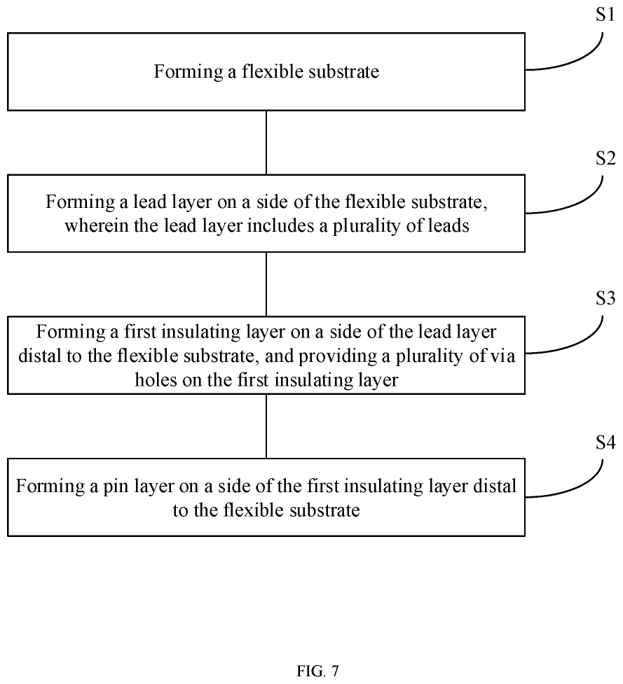

The exemplary embodiment further provides a method of manufacturing a flexible circuit board. As shown in FIG. 7, it is a flowchart of an exemplary embodiment of the method of manufacturing a flexible circuit board of the present disclosure. And the method includes:

step S1: forming a flexible substrate;

step S2: forming a lead layer on a side of the flexible substrate, wherein the lead layer includes a plurality of leads;

step S3: forming a first insulating layer on a side of the lead layer distal to the flexible substrate, and providing a plurality of via holes on the first insulating layer, wherein orthographic projections of the via holes on the flexible substrate partially covers orthographic projections of the leads on the flexible substrate; and

step S4: forming a pin layer on a side of the first insulating layer distal to the flexible substrate, wherein the pin layer includes a plurality of pins, and is disposed on the side of the first insulating layer distal to the flexible substrate, and the pins are correspondingly connected with the leads through the via holes.

The above steps are described in detail below:

In step S1, since the flexible circuit board needs to be transferred a plurality of times among the respective devices during the manufacturing process, forming the flexible substrate may include forming the flexible substrate on a rigid substrate to facilitate the transfer of the flexible substrate. The rigid substrate can be a glass substrate. The flexible substrate may be formed through a coating process.

In step S2, forming the lead layer on a side of the flexible substrate, may include forming the lead layer through a patterning process. The patterning process may specifically include: firstly, forming an entire conductive layer on a side of the flexible substrate, wherein the entire conductive layer may be formed by metal sputtering; then, forming a required lead layer pattern by processes such as coating photoresist, masking, exposing, and etching, etc. The conductive layer may be a metal layer.

In step S3, forming the first insulating layer on the side of the lead layer distal to the flexible substrate, may include forming the first insulating layer on the side of the lead layer distal to the flexible substrate through a vapor deposition process. In addition, providing the plurality of via holes on the first insulating layer, can be formed by a patterning process as well.

In step S4, forming the pin layer on the side of the first insulating layer distal to the flexible substrate, may include: forming an entire conductive layer on the side of the first insulating layer distal to the flexible substrate through a sputtering process; then, forming the pin layer with a preset pattern from the conductive layer through a patterning process. The conductive layer may be an indium tin oxide layer.

A plurality of the flexible circuit boards may be formed in a flexible circuit motherboard at one time through the above steps, and the flexible circuit motherboard includes a plurality of flexible circuit boards. After the flexible circuit motherboard is formed, the flexible circuit motherboard can be divided into a plurality of flexible circuit boards through a cutting process. After the flexible circuit motherboard is divided into a plurality of flexible circuit boards, the flexible circuit boards can be coated with liquid solder resist, wherein the liquid solder resist can be green oil. The liquid solder resist can increase flexibility of the flexible circuit board, and the liquid solder resist can further protect the flexible circuit board.

In the exemplary embodiment, the pin layer may include at least one pin group, each of the pin groups includes a plurality of rows of pins, each row of the pins are arranged at intervals along the first direction, and two adjacent rows of pins are staggered in the first direction. The pin layer may include a plurality of pin groups.

In the exemplary embodiment, the method of manufacturing a flexible circuit board further includes: disposing a second insulating layer between the flexible substrate and the lead layer, wherein the second insulating layer may be formed of silicon oxide (SiOx) material. The second insulating layer formed of the SiOx material has the effect of isolating water and oxygen, and can prevent organic matter and moisture in the flexible substrate from affecting the subsequent processes.

In the exemplary embodiment, orthographic projections of the plurality of leads on the flexible substrate may be arranged at intervals along the first direction and extend along the second direction, wherein the first direction and the second direction may intersect. The lead may include: a wiring part and a connecting part, wherein an orthographic projection of the wiring part on the flexible substrate may extend along the second direction, the connecting part is connected to the wiring part, a size of the connecting part in the first direction may be larger than a size of the wiring part in the first direction, the orthographic projection of the via hole on the flexible substrate may be located on an orthographic projection of the connecting part on the flexible substrate, and the pin is connected to the connecting part through the via hole.

In the exemplary embodiment, a size of the pin in the first direction may be larger than the size of the connecting part of the corresponding lead in the first direction, and in the first direction, an orthographic projection of the pin on the flexible substrate can cover the orthographic projection of the corresponding connecting part on the flexible substrate.

In the exemplary embodiment, each of the pins may be connected to the lead through a plurality of via holes.

In the exemplary embodiment, the orthographic projections of the plurality of via holes used for connecting the same lead, on the flexible substrate, may be arranged at intervals along the second direction.

The method of manufacturing a flexible circuit board can form the above-mentioned flexible circuit board, and the method of manufacturing a flexible circuit board has the same technical features and technical effects as that of the above-mentioned flexible circuit board, which will not be repeated here.

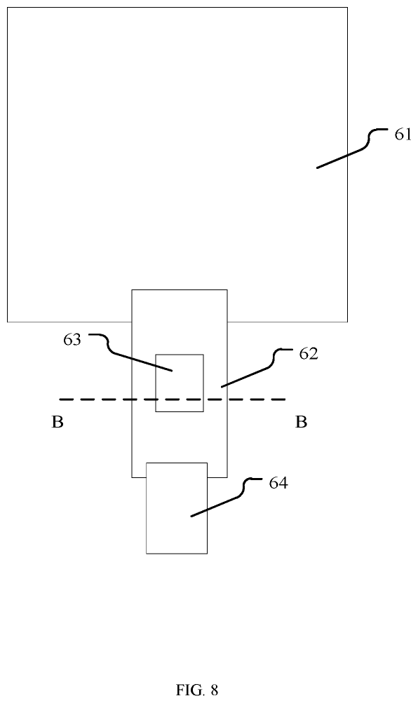

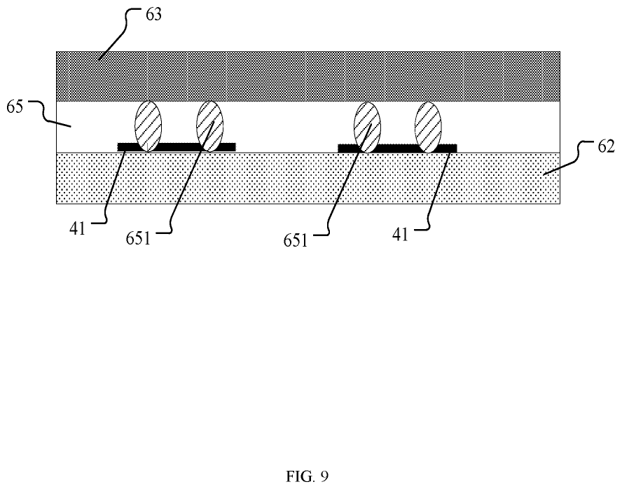

The exemplary embodiment further provides a display module, as shown in FIGS. 8 and 9, FIG. 8 is a schematic structural diagram of an exemplary embodiment of the display module of the present disclosure, and FIG. 9 is a cross-sectional view of the dashed line B-B in FIG. 8. The display module includes: a display panel 61, an above-mentioned flexible circuit board 62, a driving chip 63, and a control motherboard 64. The flexible circuit board 62 can be bound to the display panel 61 through an anisotropic conductive adhesive film. The driving chip 63 is bound to the flexible circuit board 62 through an anisotropic conductive adhesive film 65. The control motherboard 64 is bound to the flexible circuit board 62 through an anisotropic conductive adhesive film.

As shown in FIG. 9, the anisotropic conductive adhesive film 65 contains conductive particles 651, and the driving chip 63 can be connected to the pins 41 on the flexible circuit board 62 through the conductive particles 651.

The driving chip may include a source driving circuit for generating data signals, a touch signal driving circuit for generating touch signals, and the like. The control motherboard may include a clock control circuit for generating a clock signal and a control signal. The clock signal and the control signal may be used to control a circuit such as the source drive circuit, the touch signal drive circuit, etc., to generate corresponding drive signals. By bending the flexible circuit board, the driver chip and the control motherboard can be encapsulated on the back of the display panel, thereby reducing the width of frame of the display panel.

Those skilled in the art will easily think of other embodiments of the present disclosure after considering the description of the present disclosure and practicing the disclosure disclosed herein. This application is intended to cover any variations, uses, or adaptive changes of the present disclosure. These variations, uses, or adaptive changes follow the general principles of the present disclosure and include common knowledge or conventional technical means in the technical field that are not disclosed in the present disclosure. The description and embodiments of the present disclosure are only regarded as exemplary, and the true scope and spirit of the present disclosure are pointed out by the appended claims.

It should be understood that the present disclosure is not limited to the precise structure that has been described above and shown in the drawings, and various modifications and changes can be made without departing from its scope. The scope of the present disclosure is limited only by the appended claims.

1. A flexible circuit board, comprising:
a flexible substrate;
a lead layer, comprising a plurality of leads, and arranged on a side of the flexible substrate;
a first insulating layer, arranged on a side of the lead layer distal to the flexible substrate, wherein a plurality of via holes are provided in the first insulating layer, and orthographic projections of the via holes on the flexible substrate at least partially overlap with orthographic projections of the leads on the flexible substrate; and
a pin layer, comprising a plurality of pins, and provided on a side of the first insulating layer distal to the flexible substrate, wherein the plurality of pins are arranged in a one-to-one correspondence with the plurality of leads, and the pins are connected to the corresponding leads through the via holes.

2. The flexible circuit board according to claim 1, further comprising:
a second insulating layer, disposed between the flexible substrate and the lead layer.

3. The flexible circuit board according to claim 1, wherein the pin layer comprises at least a pin group, each of the pin groups comprises a plurality of rows of the pins, each row of the pins are arranged at intervals along a first direction, and two adjacent rows of the pins are staggered in the first direction.

4. The flexible circuit board according to claim 3, wherein the pin layer comprises two rows of the pins.

5. The flexible circuit board according to claim 3, wherein the pin layer comprises a plurality of the pin groups.

6. The flexible circuit board according to claim 1, wherein the orthographic projections of the plurality of leads on the flexible substrate are arranged at intervals along a first direction, and extend along a second direction, the first direction intersects with the second direction, and the lead comprises:
a wiring part, wherein an orthographic projection of the wiring part on the flexible substrate extends along the second direction; and
a connecting part, connected to the wiring part, wherein a size of the connecting part in the first direction is larger than a size of the wiring part in the first direction,
wherein the orthographic projection of the via hole on the flexible substrate is located on an orthographic projection of the corresponding connecting part on the flexible substrate, and the pin is connected to the corresponding connecting part through the via hole.

7. The flexible circuit board according to claim 6, wherein a size of the pin in the first direction is larger than a size of the connecting part of the corresponding lead in the first direction, and in the first direction, an orthographic projection of the pin on the flexible substrate cover the orthographic projection of the corresponding connecting part on the flexible substrate.

8. The flexible circuit board according to claim 7, wherein each of the pins is connected to the corresponding lead through a plurality of the via holes.

9. The flexible circuit board according to claim 8, wherein the orthographic projections of the plurality of via holes for connecting a same one of the leads, on the flexible substrate are arranged at intervals along the second direction.

10. The flexible circuit board according to claim 2, wherein the second insulating layer is formed of silicon oxide material.

11. A method of manufacturing a flexible circuit board, comprising:
forming a flexible substrate;
forming a lead layer on a side of the flexible substrate, wherein the lead layer comprises a plurality of leads;
forming a first insulating layer on a side of the lead layer distal to the flexible substrate, and providing a plurality of via holes on the first insulating layer, wherein orthographic projections of the via holes on the flexible substrate at least partially overlap with orthographic projections of the leads on the flexible substrate; and
forming a pin layer on a side of the first insulating layer distal to the flexible substrate, wherein the pin layer comprises a plurality of pins, and is are disposed on the side of the first insulating layer distal to the flexible substrate, the plurality of pins are arranged in a one-to-one correspondence with the plurality of leads, and the pins are connected to the corresponding leads through the via holes.

12. The method of manufacturing a flexible circuit board according to claim 11, further comprising:
forming a second insulating layer between the flexible substrate and the lead layer.

13. The method of manufacturing a flexible circuit board according to claim 11, wherein the pin layer comprises at least a pin group, each of the pin groups comprises a plurality of rows of the pins, each row of the pins are arranged at intervals along a first direction, and two adjacent rows of the pins are staggered in the first direction.

14. The method of manufacturing a flexible circuit board according to claim 11, wherein the orthographic projections of the plurality of leads on the flexible substrate are arranged at intervals along a first direction, and extend along a second direction, the first direction intersects with the second direction, and the lead comprises:
a wiring part, wherein an orthographic projection of the wiring part on the flexible substrate extends along the second direction; and
a connecting part, connected to the wiring part, wherein a size of the connecting part in the first direction is larger than a size of the wiring part in the first direction,
wherein the orthographic projection of the via hole on the flexible substrate is located on an orthographic projection of the corresponding connecting part on the flexible substrate, and the pin is connected to the corresponding connecting part through the via hole.

15. A display module, comprising:
a display panel;
the flexible circuit board according to claim 1, wherein the flexible circuit board is bound to the display panel through an anisotropic conductive adhesive film;
a driving chip, bound to the flexible circuit board through an anisotropic conductive adhesive film; and
a control motherboard, bound to the flexible circuit board through an anisotropic conductive adhesive film.

16. The display module according to claim 15, further comprising:
a second insulating layer, disposed between the flexible substrate and the lead layer.

17. The display module according to claim 15, wherein the pin layer comprises at least a pin group, each of the pin groups comprises a plurality of rows of the pins, each row of the pins are arranged at intervals along a first direction, and two adjacent rows of the pins are staggered in the first direction.

18. The display module according to claim 17, wherein the pin layer comprises two rows of the pins.

19. The display module according to claim 17, wherein the pin layer comprises a plurality of the pin groups.

20. The display module according to claim 15, wherein the orthographic projections of the plurality of leads on the flexible substrate are arranged at intervals along a first direction, and extend along a second direction, the first direction intersects with the second direction, and the lead comprises:
a wiring part, wherein an orthographic projection of the wiring part on the flexible substrate extends along the second direction; and
a connecting part, connected to the wiring part, wherein a size of the connecting part in the first direction is larger than a size of the wiring part in the first direction,
wherein the orthographic projection of the via hole on the flexible substrate is located on an orthographic projection of the corresponding connecting part on the flexible substrate, and the pin is connected to the corresponding connecting part through the via hole.
